(19) United States
(12) Patent Application Publication
(10) Pub. No.: US 2002/0101135 A1
(43) Pub. Date: Aug. 1, 2002

(54) Method and device for noise damping

(76) Inventors: Marco Giovanardi, Melrose, MA (US); Emanuele Bianchini, Winchester, MA (US)

Correspondence Address: TESTA, HURWITZ & THIBEAULT, LLP, HIGH STREET TOWER, 125 HIGH STREET, BOSTON, MA, 02110, US

(21) Appl. No.: 09/916,360

(22) Filed: Jul. 26, 2001

Related U.S. Application Data
(60) Provisional application No. 60/221,659, filed on Jul. 28, 2000.

(51) Int. Cl. H01L 41/04

(52) U.S. Cl. 310/328

(57) ABSTRACT

The invention is directed to damping vibration, and audible noise in particular, using a hybrid actuator with active and passive damping components. In one aspect of the invention, the active component may be used to damp low frequency vibrations while the passive component is used to damp higher frequency vibrations. Also provided is a procedure for optimizing the size of each component with a minimal hybrid actuator mass. The hybrid actuator is controlled by an optimized control system.

### CROSS REFERENCE TO RELATED APPLICATIONS

This application claims priority to U.S. Ser. No. 60/221,659, filed Jul. 28, 2000, the content of which is incorporated herein by reference.

### GOVERNMENT RIGHTS TO THE INVENTION

This invention was made with Government support under contract NAS 1-00020 awarded by NASA. The government has certain rights in the invention.

### FIELD OF THE INVENTION

The invention relates generally to devices for, and methods of, damping vibration in a structure using a combination of active and passive means usable, for example, to damp vibration and thereby reduce audible noise within an aircraft.

### BACKGROUND OF THE INVENTION

The ability to reduce audible noise and vibration in, for example, passenger vehicles such as automobiles, trains and aircraft, would provide a host of benefits to the passengers riding therein. Audible noises and vibration have been shown to cause fatigue in passengers and crewpersons alike, both because of a human body's reaction to prolonged vibration and because of irritability caused by not being able to rest, sleep or concentrate while subject to noisy environments. Any system that reduces vibration and noise in vehicles would thus address a pressing need in, for example, the common-carrier industry.

While the present invention is discussed in the context of reducing vibration of vehicle parts, one of ordinary skill in the art will appreciate that the invention could be used in any context in which it is desired to damp vibration which causes an acoustical disturbance, such as noise, to reach a target, such as a listener or even vibration sensitive equipment. Thus, while the present invention is illustrated by reducing noise reaching airplane passengers, the invention would be equally applicable in reducing acoustic disturbances in vibration and/or sound-sensitive environments. These acoustic disturbances, if detectable by a target in the form of unwanted noise or vibration, can adversely impact equipment or organisms functioning within the sensitive environment.

Active damping of sound radiation has in the past struggled to find its market in high-volume production applications. While many different applications have been proposed, few of these applications have reached the commercial stage. One reason for this commercial failure is that broadband control, which is often used in conjunction with active damping, very quickly reaches its limits in terms of variability allowed to the structure. While it is possible to design an accurate broadband control law for a controlled environment, it may be difficult to do so for a variable environment or for structures with high modal density, such as thin plates.

While generally not well-suited for application to damp wide ranges of frequency, single mode control laws can be sufficiently stable to deal with the environmental changes a structure undergoes during its lifetime, but typically does so in low frequency or low modal density applications. Existing control systems are thus, by in large, inadequate to govern operation of active control systems over complex and unpredictable system conditions.

Passive methods for broadband sound reduction have been somewhat successful in the past, particularly in high frequency, high modal density applications. Passive methods are also generally more efficient at higher frequency in terms of weight and cost. However, passive methods are typically limited in terms of dynamic response and often do not provide acceptable low frequency vibration damping.

While both active and passive control separately have been shown to be at least somewhat effective in tests, only passive solutions are actually used, for example, in current aeronautical structures because of the general lack of reliability of complex active systems and their attendant design difficulties. Passive damping systems, however, have significant weight drawbacks and are not very efficient at low frequencies.

While the concept of combining active and passive materials is not new, most prior attempts have concentrated on improving the damping characteristics of the passive material by replacing the inactive constraining with a layer of active material to increase the shear in the passive layer through activation of the active layer (a method called ACLD or Active Constrained Layer Damping). ACLD slightly increases the performance of the passive layer, but does not make full use of the active layer because of the soft viscoelastic (passive) layer residing between the active layer and the structure. Therefore, ACLD can provide some benefit over a purely passive system by using an active layer, but is unlikely to provide good performance for both the passive and the active parts.

It would thus be desirable to have a vibration reduction system involving active and passive damping, or “hybrid” damping, operating under the rules of an optimal control system. Since this vibration reduction system would involve both active and passive damping, the system would incorporate the advantages of each respective damping type. The system would further provide a relatively low weight solution with high performance over a large range of frequencies.

### SUMMARY OF THE INVENTION

In accordance with the present invention, there are provided systems and methods that address the shortcomings of prior hybrid vibration dampers.

Thus, according to one aspect of the invention, a device for reducing vibration in a section of material is provided, where the vibration causes an acoustic disturbance in a range of frequencies detectable by a target. The device includes an active damper including an electroactive element in electrical communication with an electrode. The active damper os located a first distance from the section of material. The device also includes a passive damper comprising a sound reducing material. The passive damper is located a second distance from said section of material. The second distance is greater than the first distance. At least one of the active damper and the passive damper reduces the magnitude of the acoustic disturbance reaching the target.

According to another aspect of the invention, a control system is provided, where the control system is created by modeling the desired response of a hybrid actuator in order to optimize the characteristics of both the active and passive damping materials.

According to yet another aspect of the invention, a method of damping vibration in a section of material, where the vibration causes noise audible to a human ear, is provided. The method includes bonding an actuator with active damping means and passive damping means to a desired portion of the section of material and activating the active damping means to damp low frequency vibration in the section of material. The active damping means and the passive damping means together reduce noise to a greater extent than would be possible if the active damping means or the passive damping means act alone.

### BRIEF DESCRIPTION OF THE DRAWINGS

FIG. 1 is a three dimensional plot illustrating a cost function for a viscoelastic material as a function of material loss factor and dynamic modulus.

FIGS. 2 and 3 illustrate one embodiment of a hybrid damper according to the invention attached to an existing structure.

FIG. 4 is a plot illustrating a cost function used to calculate an optimal thickness of an actuator used in a hybrid damper according to the invention.

FIG. 5 illustrates one possible layout of actuators and viscoelastic elements on a test plate.

FIG. 6 is a schematic illustration of a feedback control loop according to the invention.

FIG. 7a illustrates the test setup for sound testing a plate for vibration reduction. FIG. 7b illustrates the layout of accelerometers on the plate used in conjunction with sound testing.

FIG. 8 illustrates the change in sound radiation as a function of the amount of viscoelastic material used on a test plate.

FIG. 9 illustrates the reduction in sound radiation using hybrid dampers according to the invention.

### DETAILED DESCRIPTION

The present invention proposes, in one embodiment, to use the viscoelastic characteristics of a hybrid damper for broadband high-frequency damping and the characteristics of a piezoceramic element for active damping of a few low-frequency modes. Further, in contrast to ACLD systems where the piezoceramic is being used on the outside of the viscoelastic with respect to the structure, the present invention, in one embodiment, locates the piezoceramic on the inside with respect to the structure.

Behavioral models are also presented usable to generate novel control systems and to help place and size the active and passive elements correctly. The new models are presented, in part, because simple existing models based on Bernoulli-Euler or Kirchoff descriptions of the structure and the damper are insufficient to describe the dissipation mechanism in the viscoelastic, while traditional laminate Timoshenko or Mindlin models do not take advantage of the many simplifications that can be introduced into this model.

By way of example, the present invention can be applied to reduce the noise radiated by an airplane interior panel, where the noise is caused by vibration of the panel itself. Since such a disturbance generally is a random signal, the output noise generated is not limited to the modal response of the panel at the frequencies corresponding to the best sound radiating modes. It is thus desirable to reduce the peak response by actively damping the most important modes, and also to reduce the overall response of the panel by passively damping all of the modes. In order to provide a common set of terminology for use in the detailed description of the present invention that follows, a list of nomenclature is provided as Table 1.

TABLE 1

| | |
|---|---|
| E | generalized Young's modulus of the structure |
| | (E = E(y)) |
| E* | complex modulus for viscoelastic material |
| | representation |
| E′ | real part of the complex modulus |
| E″ | imaginary part of the complex modulus |
| η | ratio between imaginary and real part of the |
| | modulus, called the loss factor of the material |
| G | real part of the complex shear modulus |
| Eₚ | Young's modulus of the actuator element |
| Eₛ | Young's modulus of the base structure |
| σ | stress in the structure; σₓ stress in x-direction |
| ε | strain in the structure; eₓ strain in x-direction |
| ε₀ | extensional strain in the structure at the frame |
| | of reference |
| κ | curvature of the Bernoulli-Euler structure |
| | axis |
| Fₚ | extensional force of the actuator |
| | actuator element with respect to the neutral axis. |
| tₚ | thickness of the actuator |
| d | distance between actuator centerline and |
| | neutral axis of the structure |
| Λ | free extensional strain of the actuator |
| F | force resultant of the cross section |
| M, Mᵣ | moment resultant (with reference to the frame r) |
| y, yᵣ | vertical coordinate (with reference to the frame r) |
| A | cross section area |
| T | transformation matrix between frames of |
| | reference |
| K | compensator |
| s | Laplace variable |
| ζ | damping of compensator poles |
| ωₚ | frequency of compensator poles |
| z | vertical distance between frames of reference |
| n | distance between frame of reference and neutral |
| (EI)ₙ | combined bending stiffness of the structure and |
| tₛ | structural thickness underneath the actuator |
| (EI)ₛ | combined bending stiffness of the structure with |
| | an actuator on one side |

The present invention is illustrated herein by way of a detailed example of one possible way to construct the inventive hybrid actuator. One of ordinary skill in the art will understand that other steps and considerations are usable in constructing hybrid actuators according to the invention. For example, instead of viscoelastic passive damping, as described below, other passive means could be implemented, such as high rigidity stiffeners and compressible foams and liquids. Similarly, active damping is not limited to piezoelectric actuators, but could include, by way of example, engageable non-piezoelectric supports and struts or linear electromagnetic actuators.

The example presented below details the steps one of ordinary skill might take to construct a hybrid actuator according to the present invention. The example illustrates selection of a passive damping material (in the example, a viscoelastic material), creating a control system for use in governing the hybrid actuator, designing an optimal hybrid actuator and testing the control system and hybrid actuator to verify vibration reduction and sound damping.

Generally speaking, in the modeling phase of actuator construction, a model is developed to describe the behavior of a hybrid actuator containing a piezoceramic layer, a viscoelastic layer and a constraining layer in various configurations and thicknesses and with different material characteristics for the viscoelastic material and the constraining layer. This effort is used to determine the optimal characteristics of a hybrid damper according to the invention, and therefore to select appropriate materials to use in constructing the damper.

For purposes of a test structure in the example provided herein, an aluminum panel similar to exterior panels in airplanes is chosen and a hybrid damping system implemented on this structure. In this example, the panel or plate employed in the example is approximately 10″ (ten inches) wide by 14″ (fourteen inches) height by 0.04″ (four hundredths of an inch) thick. An anechoic transmission loss facility is used as a basis for comparison to determine the reduction in radiated sound achieved by the hybrid damping system, with the panel bolted into a wall and excited by a speaker on one side of it. The feedback compensator for the active part of the damping system is designed as a simple combination of positive position feedback (PPF) filters, and implemented on a digital signal processing (DSP) board. The resulting sound radiation from the excited panel shows the effect of the hybrid damper, for example, by achieving reduction in sound both in the low and high frequencies within the chosen band of interest, and with the least amount of added weight or added complexity typically attributable to an active system. The total added mass to the aluminum panel in the example is only about 50g, which is small compared to the amount of mass a passive system operating alone to achieve a similar result would weigh for the same structure.

### MODELING THE PASSIVE, SOUND REDUCING MATERIAL

The behavior of viscoelastic materials is generally modeled through a macroscopic approach, which encompasses theories based on the phenomenological aspects of physics. One such approach entails using experimental data to build a mathematical model for each specific material being considered for use in the actuator. One method used is called the standard nonlinear model, where the relationship between stress and strain in the material is expressed using the first derivatives in time of both the stress and the strain in the material. It is a more complex representation of the material properties than either Hooke's law or the simple dashpot-spring combination (which uses the time-derivative of strain, but not of stress). It can be expressed as

$$σ + α \frac{ⅆ σ}{ⅆ t} = E ϵ + β \frac{ⅆ ϵ}{ⅆ t}$$

This model can be generalized by adding successive derivatives of σ and ε. If we assume a harmonic input, this equation can be simplified to

σ=E^{*}(ω)ε=[E′(ω)+iE″(ω)]ε=E′(ω)[1+η(ω)]ε

which is known as the complex modulus approach, expressed in the frequency domain. The two parameters in the last part of this equation, E′ and η, are functions of frequency and temperature, and are normally given to characterize a viscoelastic material. In this equation, E′ is the real part of the modulus, E″ the imaginary part, and η is the ratio between the two, called the loss factor of the material. The two parameters in the last part of this equation, E′ and η, are functions of frequency and temperature, and are normally diagrammed to characterize a viscoelastic material.

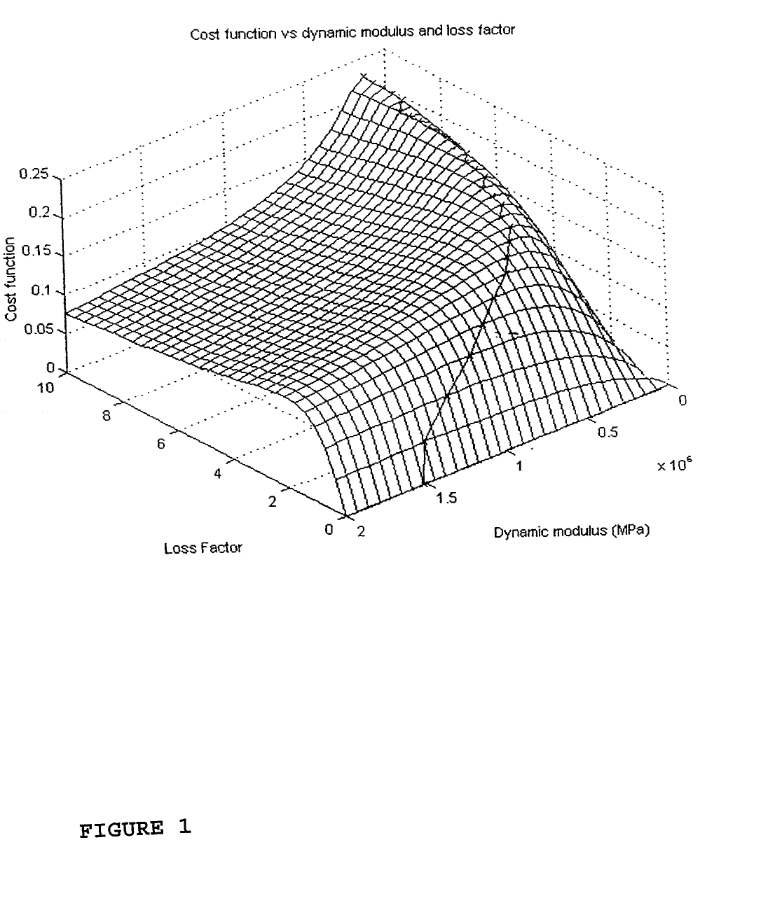

One goal of the modeling effort is to determine the optimal characteristics of the viscoelastic element to be used. To achieve this, a cost finction is chosen for the model. The cost function arises from the amount of strain energy that goes into the shear layer in any given configuration as a ratio of the total strain energy in the structure for a given deformation shape. In this example, a simple metal cantilever beam is used to observe the damping reaction, though any suitable mechanical test for inducing and measuring vibration may be used. The deformation shape is calculated based on either a static tip force, or dynamic mode shapes, and any of the parameters could be varied or chosen to be constant. FIG. 1 shows the shape of the cost function for a static deflection of the beam and as a function of the viscoelastic material properties, the shear modulus G and the dynamic loss factor η.

The cost finction gradients both in G and η are fairly low around the optimal value, and then drop off rapidly towards higher stiffness and lower loss factor. Since the two parameters are linked through the material composition, it may be difficult to find materials with high loss factors that are still stiff enough, or with high stiffness that have a good loss factor. Most of the damping materials available commercially have a loss factor which is not much higher than 1, and the optimal value for the dynamic modulus G is therefore close to 5×10⁵ Pa.

Optimizing the model for multiple parameters, it is also possible to find the optimal thickness and material of the constraining layer (in this example, aluminum), and the optimal thickness of the viscoelastic layer. The results obtained are consistent with a model containing a 0.005″ thick layer of viscoelastic, and a 0.010′ thick layer of aluminum.

### OPTIMAL ACTUATOR THICKNESS

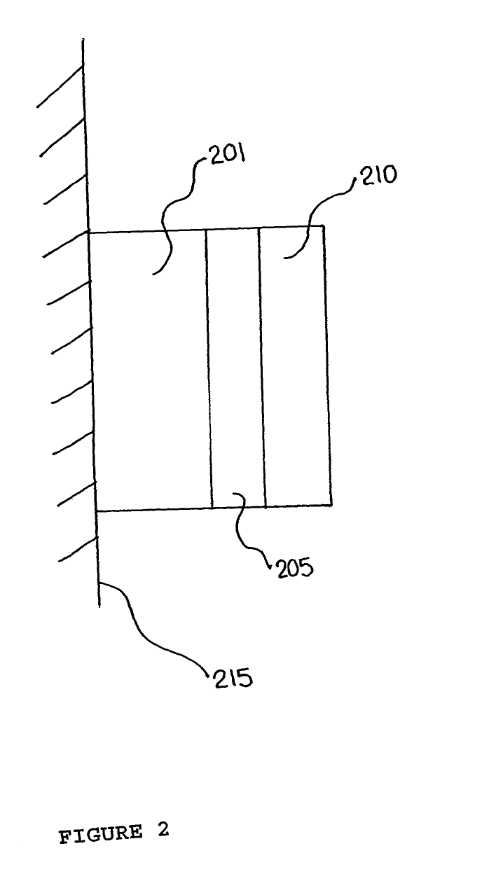

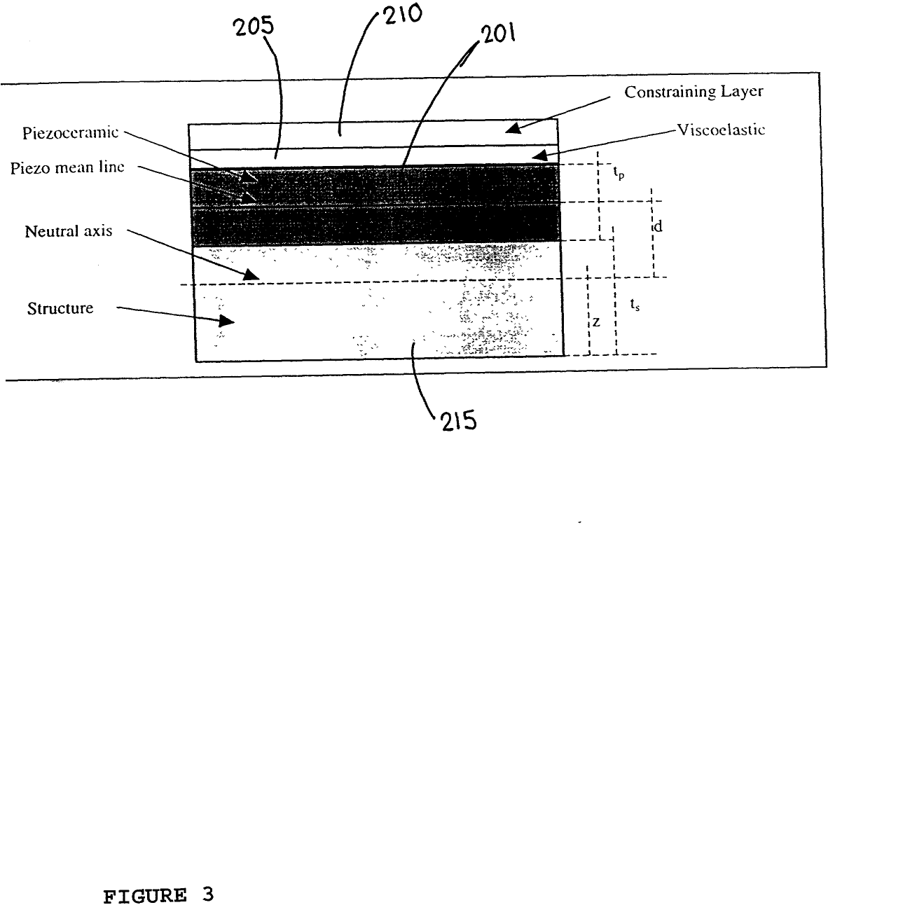

The optimal actuator thickness is found by optimizing the induced strain that the actuator can theoretically produce on the structure, in this case, the airplane panel. FIGS. 2 and 3 show a simplified model of the cross section of the panel in presence of an actuator bonded to one side. In particular, FIG. 2 illustrates a structure 215, such as an airplane panel, to which is attached a hybrid actuator according to the invention. Starting at the surface of the structure 215, an electroactive element 201, such as a piezoelectric layer, is attached to the structure 215. On an opposing surface of the electroactive element 201 is attached an additional sound reducing material 205, such as a viscoelastic material chosen, optionally, using the considerations and methods detailed herein. The hybrid actuator, at a minimum, includes the electroactive element 201 and the sound reducing material 205. Also included in the hybrid actuator of the present invention is an electrode (not shown), which is in electrical communication with the electroactive element 201. The electrode, when energized, can cause a deformation in the electroactive element 201. The deformation can, for example, be controlled by a digital signal processor (DSP)-based mathematical controller which commands appropriate deformation of the electroactive element 201 based on either the vibration, the acoustic disturbance, or both. Conversely, a deformation in the electroactive element 201 can be electrically dissipated by converting the mechanical energy of the deformation into electrical energy that is fed to the electrode and subsequently dissipated by a shunt or other means. Optionally, the sound reducing material 205 is, in turn, attached to a constraining layer, 210, which as discussed in the context of the example shown here, may be aluminum.

Two factors combine in the calculation of the induced strain when the structure is assumed given and therefore the only variable in the system is the actuator thickness tₚ: the neutral axis moves toward the piezoceramic by increasing the thickness of the piezoceramic, and the cross-section bending stiffness also increases with thickness of the piezoceramic.

The strain an actuator can induce can be calculated as:

$$ϵ ∝ κ = \frac{{F}_{p} d}{{EI}_{s}} \qquad ( 1 )$$

where k is the curvature, Fₚ is the extensional force of the actuator element per unit surface area, d is the distance between the middle of the actuator and the neutral axis of the structure, and EIₛ is the combined bending stiffness of the structure with the actuator on one side. The extensional force a piezoceramic element can give can be written, under the assumption of pure strain actuation, as:

Fₚ=EₚtₚΛ (2)

In this equation, A is the extensional strain and Eₚ is the Young's modulus of the actuator. Writing the equilibrium equation for a mechanical system with an arbitrary frame of reference the following relation is obtained:

$${\{ \begin{matrix}θ \\ u\end{matrix} \}}_{r} = [ \begin{matrix}{( EI )}_{r} & {( ES )}_{r} \\ - {( ES )}_{r}^{T} & {( EA )}_{r}\end{matrix} ] {\{ \begin{matrix}M \\ F\end{matrix} \}}_{r} \qquad ( 3 )$$

where θ is the vector containing the rotations around the reference axes, u is the vector containing the displacements from those axes, EI is the second order mass moment around the reference axis, ES is the first order or static moment around the same axis, and EA is the zero moment or stiffniess of the structure. The index r in the equation shows that the terms are calculated with respect to a frame of reference r. The three structural moments are defined as:

$$\begin{matrix}{( {S}^{2} )}_{r} = {( EI )}_{r} = {\int }_{A} {Ey}_{r}^{2} ⅆ A \\ {( {S}^{1} )}_{r} = {( ES )}_{r} = {\int }_{A} {Ey}_{r} ⅆ A \\ {( {S}^{0} )}_{r} = {( EA )}_{r} = {\int }_{A} E ⅆ A\end{matrix}$$

The neutral axis of a structure is defined as the axis along which the equilibrium equations of a structure are uncoupled between rotations and displacements. In other words, to find the neutral axis of a structure, the static moment S¹ must be 0. Writing equation 3 for a different frame of reference, moved by z, gives:

$${\{ \begin{matrix}M \\ F\end{matrix} \}}_{rz} = [ \begin{matrix}{( EI )}_{rz } & {( S )}_{rz } \\ - {( S )}_{rz }^{T} & {( {S}^{0} )}_{rz }\end{matrix} ] {\{ \begin{matrix}ϑ \\ u\end{matrix} \}}_{rz}$$

$${\{ \begin{matrix}M \\ F\end{matrix} \}}_{rz} = [ \begin{matrix}1 & - z \\ 0 & 1 \end{matrix} ] {\{ \begin{matrix}M \\ F\end{matrix} \}}_{r} = T {\{ \begin{matrix}M \\ F\end{matrix} \}}_{r}$$

$${\{ \begin{matrix}ϑ \\ u\end{matrix} \}}_{r} = {T}^{T} {\{ \begin{matrix}ϑ \\ u\end{matrix} \}}_{rz}$$

where the force and displacement vectors have been re-written with a coordinate system change described by the transformation matrix T. From this equation it can be derived that:

$$[ \begin{matrix}{( EI )}_{rz} & {( S )}_{rz} \\ - {( S )}_{{rz}^{T} } & {( {S}^{0} )}_{rz}\end{matrix} ] = T [ \begin{matrix}{( EI )}_{r} & {( S )}_{r} \\ - {( S )}_{r}^{T} & {( {S}^{0} )}_{r}\end{matrix} ] {T}^{T} = [ \begin{matrix}{( EI )}_{r} + z ( {( S )}_{z}^{T} - ( S ) ) + {{z}^{2} ( {S}^{0} )}_{z} & {( S )}_{z} - {z ( {S}^{0} )}_{z} \\ - {( S )}_{z}^{T} - {z ( {S}^{0} )}_{z} & {( {S}^{0} )}_{z}\end{matrix} ]$$

Comparing terms with equation 3, we can extract:

$${( S )}_{rz} = {( S )}_{r} - {z ( {S}^{0} )}_{r} if {( S )}_{rz} = 0 ⇒ z = {( {S}^{0} )}_{r}^{- 1} {( S )}_{r} \qquad ( 4 )$$

which gives the location of the neutral axis. For the test structure, therefore, equation 1 can be rewritten, using equations 2 and 4 and expressing d in terms of tₛ, tₚ and z, as:

$$ϵ = const . \cdot Λ \frac{{E}_{p} {t}_{{p}_{p}} ( {t}_{s} + 1 / 2 {t}_{p} - {( {S}^{0} )}_{r}^{- 1} {( S )}_{r}}{{( {EI}_{s} )}_{r}}$$

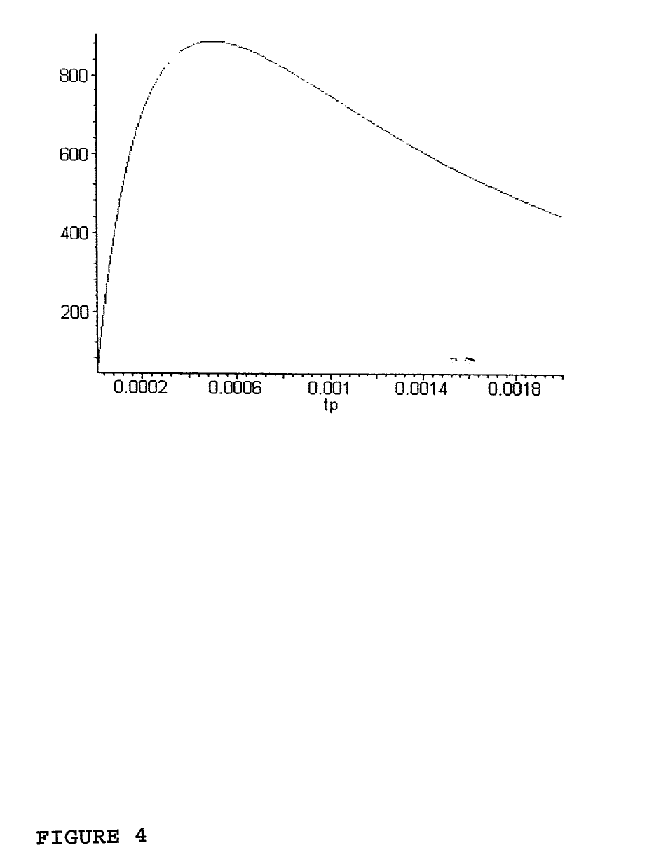

for a chosen frame of reference. Since the numerator is a second order polynomial in tₚ and the denominator a third order polynomial in tₚ, there is a local maximum for this flnction which can be calculated. The cost function has the shape displayed in FIG. 4.

In the present case, with Eₚ=69Gpa, Eₛ=210Gpa, t_{S}=.9 mm, the following numbers are obtained:

$$\{ \begin{matrix}d = 0.63 mm \\ {tp}_{opt} = 0.72 mm = {0.0285}^{″}\end{matrix}$$

Based on these results, an appropriate active damping element is selected. One possible damper is a QuickPack® actuator made by Active Control eXperts, Inc. of Cambridge, Mass. having two layers of piezoceramic and a total thickness of around 0.030″.

### OPTIMAL ACTUATOR LOCATION AND SIZE

In general, the inventors have found that best locations for induced-strain actuators are the areas where the actuators ‘capture’ the most amount of strain in a given mode shape. Therefore, knowing the mode shapes of the modes to control, the optimal location for control actuators and sensors can be determined. Since the mode shapes of a large plate are similar to sine waves, the mode shapes can be approximated using, for example, analytical computer software. The first step is to identify the lowest radiating modes. In a simple rectangular plate with an aspect ratio close to one, the first three sound radiating modes are the (1,1,), (1,3) and (3,1) modes.

In a first approximation, the authority of an actuator over a given mode is proportional to the difference in rotation between opposite edges. This occurs over areas where there is the highest strain (strain being the spatial derivative of rotation, or the places where there are the greatest gradients of rotation), while areas with low strain or opposite sign in strain on opposing edges will give low performance. For the three modes selected here, the best actuator location is in the center of the plate, which corresponds to the high strain location for all three modes. In general, this can be said for all the radiating modes if the sound is measured in the near field in the middle of the plate.

Once the location and thickness of the hybrid actuators are determined, the last consideration to be addressed is the size and number of actuators to place. Considerations important to this latter determination are the amount of current needed to drive the actuators, the surface area to be covered (which, optionally, may be chosen to be as small as possible), the difficulty and cost of building and wiring extended actuators on the upper side of the panel, and the performance of the system on the lower side of the panel.

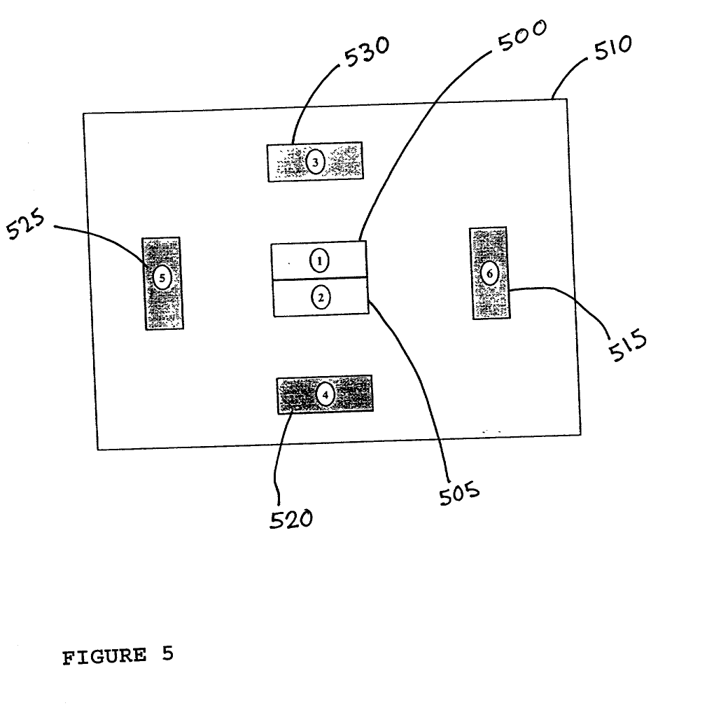

One possible configuration has the layout shown in FIG. 5. In FIG. 5, the plate 510 has bonded to it the hybrid actuators 500, 505. The plate 510 of FIG. 5 is also shown with additional constrained layer viscoelastic pieces 515, 520, 525 and 530, that provide additional damping but are not necessary to damp vibration according to the invention.

### CALCULATING SOUND PRESSURE

To calculate the sound radiated from a plate, we must make certain assumptions are made. First, it is assumed that all the sound heard is coming from the variation in air pressure caused by the movement of the plate. This implies that there is no sound reflecting off any other surfaces in the immediate surroundings (like walls, for example), and that there is no sound coming from other sources than the plate. In general, for a sufficiently large and quiet room, these assumptions are true, and for tests done in an anechoic chamber this is especially true. Next, it is assumed that the position of the listener is known, and is directly in front of the plate at a sufficient distance. This assumption is made because the sound field varies from point to point, and in general, it could be possible to reduce the sound radiated to a certain point, while not changing the sound radiated to another point at all. A mathematical assumption useful to explain the problem, and which contains the two assumptions mentioned above, is that the panel is a “baffled plate”, where the edges of the plate are attached to a non-radiating surface extending to infinity on all sides.

One more assumption is made to calculate the sound pressure radiated, which is the linearity of air as a sound carrying medium. This allows an approximation of the plate as a series of little pistons moving in the direction normal to the plate itself, representing a series of sound sources independent from each other. The sound radiated by the plate is then the sum of the sound radiated by all the little pistons. This approach is particularly convenient in presence of a finite element discretization, where the plate is already “divided” into a number of little plates, or of measurements taken on the plate with accelerometers, where the single accelerations are assumed to represent the whole piece of panel at the center of which the accelerometer is positioned. In this context, it is clear that the sound wave created by a vibrating surface depends on the shape of the vibration. For example, in the case of a simply supported plate, the modes have the shape of sine waves between the two edges. This means that the mode with a half-wave in the x direction and a half-wave in the y direction of the plate, with x andy being aligned with the edges, has every point of the surface moving in the same direction at the same time. This mode is called the (1,1) mode and corresponds to the lowest natural frequency of the plate. The modes with even wave numbers, having for example two half-sine waves in one direction and one half-sine wave in the other, called (2,1), or vice-versa, called (1,2), have half of the surface moving to one side, while the other half moves to the other side. With the assumptions made, sound radiation is weak when one part of the structure moves in one direction while another part of similar area moves in the opposite direction. The strongest sound radiating modes of a simply supported plate are therefore the odd modes, where the area of motion in one direction is much larger than the area of motion in the other.

To calculate sound pressure from the area acceleration, the Raleigh integral is used. The sound pressure radiated can be expressed as:

$$p ( {x}_{0} , {y}_{0} , {z}_{0} ) = {\int }_{S} \frac{j {ωρ}_{0} {u}_{n} ( x , y )}{2 π R} {e}^{- jkR} ⅆ S \qquad ( 5 )$$

where p is the sound pressure at the point (xₒ,yₒ,zₒ), S is the surface of the panel, ω is the frequency of the vibration, po is the density of the air, uₙ is the normal velocity of the little piston, k is the wavenumber given by k=w/c, and R is the vector distance between the measurement point and the excitation source. Since the frequency of the vibration is known, the normal acceleration can be brought into the equation instead of the normal velocity:

jωiₙ=aₙ

Two more assumptions can be made to simplify the result. One is that the listener is at a large distance compared to the distances on the plate, that is that R is constant for all the points on the plate. The second is that the listener is directly in front of the plate. With these two assumptions, the exponential term in equation 5 is constant:

$$p ( {x}_{0} , {y}_{0} , {z}_{0} ) = \frac{{ρ}_{0} {e}^{- jkR}}{2 π R} {\sum }_{r} {a}_{n} {A}_{i}$$

where now the area integral has been replaced with the sum of the contributions given by the single little pistons with surface Aᵢ. In a finite element model, the terms Aᵢ are given by the area associated to each structural node.

In order to relate this to the mode shapes in the structure, the structural system equation can be written as follows:

$$\{ \begin{matrix}M \ddot{x} + D \dot{x} + Kx = Bu \\ y = Cx\end{matrix}$$

Since the calculated mode shapes are mass-normalized, transforming the system variables into modal coordinates we get:

$$\{ \begin{matrix}x = Φ {q}_{,} \dot{x} = Φ \dot{q} , \ddot{x} = Φ \ddot{q} \\ {Φ}^{T} M Φ = I , {Φ}^{T} D Φ = diag ( 2 {ζω}_{i} ) , {Φ}^{T} K Φ = diag ( {ω}_{i}^{2} )\end{matrix} ⇒ \\ I \ddot{q} + diag ( 2 {ζω}_{i} ) \dot{q} + diag ( {ω}_{i}^{2} ) q = {Φ}^{T} Bu$$

which can be written in state-space form as:

$$\{ \begin{matrix}\{ \begin{matrix}\dot{q} \\ \ddot{q}\end{matrix} \} = [ \begin{matrix}0 & I \\ - diag ( {w}_{i}^{2} ) & - diag ( 2 {ζω}_{i} )\end{matrix} ] \{ \begin{matrix}q \\ \dot{q}\end{matrix} \} + [ \begin{matrix}0 \\ {Φ}^{T} B\end{matrix} ] u \\ y = [ C Φ 0 ] \{ \begin{matrix}q \\ \dot{q}\end{matrix} \}\end{matrix}$$

The input matrix B samples the node to which the shaker force is applied, while the output matrix C represents the displaced volume for every mode, and is calculated as:

$$C = {\int }_{A} Φ ⅆ A = {\sum }_{nodes} {w}_{i} {A}_{i}$$

where dA is the infinitesimal part of area of the plate and wᵢ is the normal displacement of the node in question. For a discrete system, like the finite element model used in this example, the integral can be reduced to the area-weighted sum of the modal displacements in the nodes, with wᵢ being the normal displacement of the i-th node for every mode, and Ai being the area associated with that node.

The system can now be written in the form:

$$\{ \begin{matrix}\dot{X} = AX + {B}_{s} u \\ y = {C}_{s} X\end{matrix}$$

To obtain the sound pressure, as explained above, the volume acceleration must be calculated. This can be obtained by substituting the vector of the accelerations, x″, for the vector of the internal states, x, in the second equation, therefore transforming the system into:

$$\{ \begin{matrix}\dot{X} = AX + {B}_{s} u \\ y = {C}_{s} AX + {C}_{s} {B}_{s} u\end{matrix}$$

Now the output vector y contains the volume acceleration of the panel in the normal direction, which allows estimation of the sound pressure level as explained above.

It should be noted in this context that the human ear does not register sound pressure equally at all frequencies, and that therefore certain mode shapes with less sound radiation can be more audible to the human ear. This is the case in the present example, as the (3,1) and (1,3) modes are “louder” to the human ear than the (1,1), because their natural frequencies are more within the audible range. The human ear's sensitivity to sound pressure is generally expressed through a curve known as “A-weighting”.

### CHOOSING THE SOUND REDUCING MATERIAL

Based on the modeling described above, the optimal viscoelastic and constrained-layer characteristics are determined. Table 2 below lists some commercially available viscoelastic materials and some of their characteristics. Based on the modeling, the optimal thickness of the viscoelastic material in this example is around 0.005″, while the optimal thickness of the constraining layer, if assumed to be of aluminum, is around 0.010″.

TABLE 2

| | Material | | Viscoelastic layer | | Constraining layer | |
|---|---|---|---|---|---|---|
| Manufacturer | Name | Designation | Type | Thickness | Type | Thickness |
| 3M | Damping | 2552 | Acrylic | 0.005” | Al | 0.010” |
| | Foil | | Viscoelastic | | | |
| | | | Polymer | | | |
| Soundcoat | Soundfoil | 10N5 | Acrylic | 0.005” | Al | 0.010” |
| | | | Viscoelastic | | | |
| | | | Polymer | | | |
| EAR | Tad Pad | | Acrylic | 0.005” | Al | 0.015” |
| | | | Viscoelastic | | | |
| | | | Polymer | | | |
| Sorbothane | Sorbothane | | Acrylic | variable | None | |
| | | | Viscoelastic | | | |
| | | | Polymer | | | |

Some of the materials were selected for their characteristics, and tested on simple beam structures in a hybrid configuration. One suitable material was found to be the “Damping Foil” from 3M, which was used for the system demonstration.

To test the different viscoelastic materials, a simple beam structure can be used and standard piezoceramic actuators bonded close to the root. The inherent damping of the structure at its first resonant frequency (around 16 Hz) is determined by measuring the ringdown with different initial amplitudes, and then fitting a single pole system to it. This process is then repeated for several beams, with and without viscoelastic material on top of the piezoelectric, with different viscoelastic materials and with different amounts of viscoelastic material.

### ACTUATOR CONFIGURATION

The actuators used for the demonstration of the concept were standard ACX QuickPack® actuators, type QP40W, and a 3M type 2552 constrained-layer viscoelastic-aluminum compound on top of the actuators. This configuration, though not ideal because of the imprecise bonding of the viscoelastic to the actuator, has the advantage of being removable for comparative testing. The configuration used consists of (across the thickness): 2 piezoceramic layers (0.010″ thick each), a viscoelastic layer (approximately 0.005″ thick), and a constraining aluminum layer (0.010″ thick). In this configuration, the complete hybrid actuator weighs 19g.

### TEST SETUP

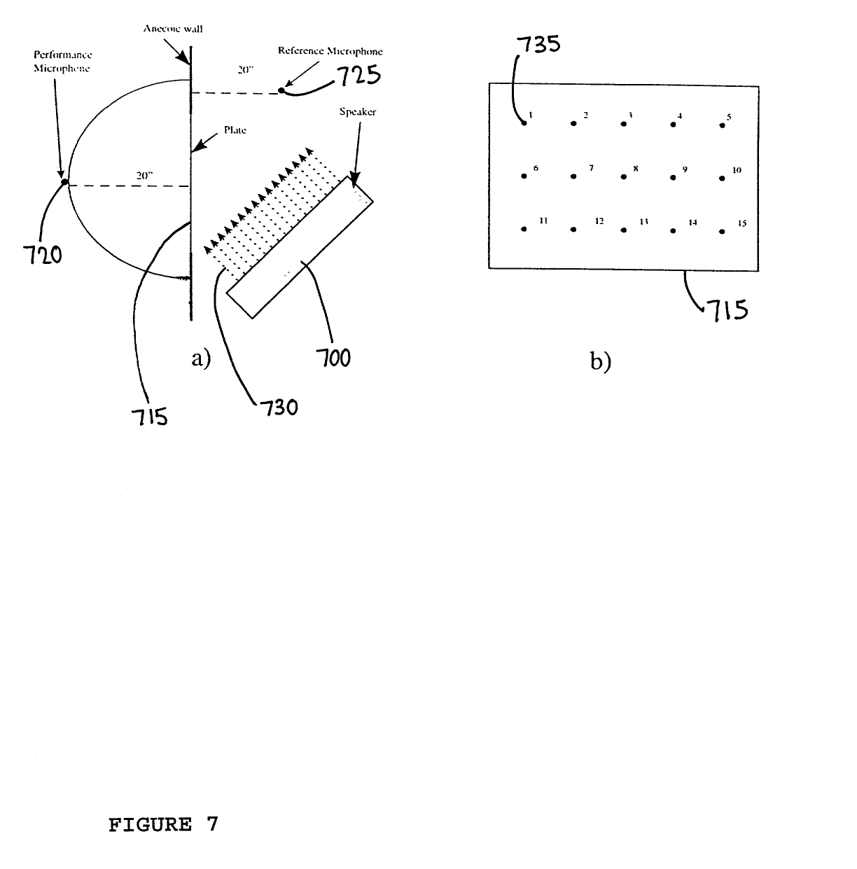

To demonstrate the concept in the context of this example, an aluminum plate of the approximate dimensions of a fuselage bay between struts is chosen, with free dimensions of the plate of about 10″×14″and a thickness of about 0.040″. The test is set up in a transmission loss facility, where the plate is bolted with a double row of bolts into an anechoic wall, excited from one side through a speaker signal and the sound and vibration is measured on the opposite side of the wall. This setup allows for the measurement of the sound radiated through the plate, while removing environmental noise. One possible setup is shown in FIG. 7a, where a speaker 700 radiates vibration inducing sound waves 730 toward a plate 715. The acoustical waves generated by the plate 715 are detected by a performance microphone 720, whose output can be compared to a reference microphone 725.

As shown in FIG. 7b, fifteen accelerometers are mounted onto the plate in this example, and one microphone is located in front of the plate on the anechoic side is used to measure the sound radiated. A random signal between 0-800 Hz is sent into the speaker, equalized such as to get a flat response from the reference microphone placed on the speaker side of the plate. The sound levels reached 100 dB on the speaker side, and about 80 dB at the performance microphone on the anechoic side. The signal from the fifteen accelerometers is then processed to model the system.

### OPEN AND CLOSED LOOP TESTING

The panel is excited with an almost flat input between 0 and 800 Hz. To obtain a good comparison between the three different types of control approaches (purely passive, purely active and hybrid), all tests are performed with viscoelastic material on and off, and with the active control on and off. The viscoelastic material was placed over the piezoceramic actuators as explained, but also in different locations on the plate.

Two of the patches are piezoelectric actuators, with viscoelastic strips on top of them for all but the “bare plate” tests. The piezoelectric actuators were never removed (they were bonded to the structure and can not be easily removed). Four of the patches are viscoelastic constrained-layer strips that are subsequently removed for the tests without passive damping.

### FEEDBACK CONTROL

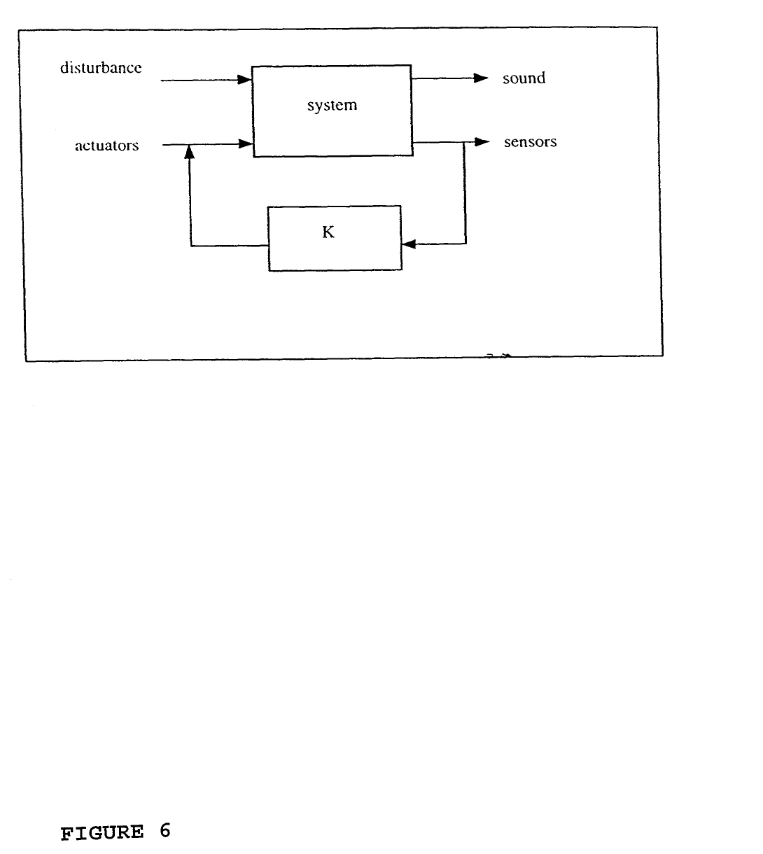

For the active control of the first few modes of vibration, a feedback control approach was used. As shown in FIG. 6, a feedback control uses a signal measured on or in the system and feeds it to a compensator K. The compensator contains a transfer function detailing how to react to a certain input, and sends an output signal to the actuators. The actuators react to the output signal and counteract the movement in the structure.

In the case of the example presented herein, the performance metric is the sound measured at a given point in front of the plate. This signal is therefore measured and used to determine the optimal control function to use in the compensator K. The signal fed back is a piezoceramic strain sensor signal from two sensors, electrically in parallel, glued to the plate close to the actuators. The placement and size of these sensors is important to get a clean and co-located function to control. “Clean” means that the signal needs to be as big as possible, or at least pick up the least amount of noise possible, while “co-located” means that for every pole in the transfer function, there is a zero close to it. This criterion is important for control design purposes and is in general obtained by placing the sensors as close as possible to the actuators. The transfer function obtained for this system is not co-located between the (1,3) and (3,1) modes, which are the second and third radiating modes. This implies that it typically marginally possible to actively reduce the sound at one of those two modes, and nearly impossible to reduce it at both of these at the same time, since a positive action on one mode produces negative effects on the other.

### CONTROL DESIGN

The advantage of a hybrid actuator over a pure active broadband control arises from the fact that the control design is obtainable without excessive calculations, since only one or two modes are targeted. In this example, the (1,1) and (1,3) modes are targeted, since they are the lowest two radiating modes, isolated from the rest of the radiating modes. To add damping to a single mode or to a limited number of distinct modes, the ideal compensator architecture is a positive position feedback or PPF. This can be achieved with a compensator containing a double complex pole coinciding with the natural frequency of the target mode. The general expression for this kind of compensator is:

$$K = \frac{1}{{s}^{2} + 2 {ζω}_{p} s + {ω}_{p}^{2}}$$

In the present example, two distinct modes are targeted with separate PPF controllers.

The control transfer function describes how the control actuators react to an input from the control sensors and is normally plotted in a frequency domain. A transfer function from actuators to sensors is collected and a model fitted to it. Based on this model description of the plate, the open and closed loop response can be simulated to determine the optimal values for the control parameters. Generally, the values for the parameters ζ and ω_{f} of for each of the two PPF filters composing the compensator are such that the closed loop poles have the greatest amount of damping. When the control gains become too high, the performance in the peak can be reduced more (the magnitude of the closed loop function can be pushed down further right underneath the peak), but this goes to the expense of a side-effect called spillover, where the closed loop transfer function is actually higher than the open loop outside of the peak, and then dips lower when it gets closer to the actual peak frequency.

The data from the fifteen accelerometers spread over the panel is summed to arrive at an average acceleration, then transformed into SPL at a given distance in front of the plate by assuming the single parts of the plate to be moving with the acceleration measured for their center. Through some filtering and calculations, the power spectral density (PSD) of the Sound Pressure Level (SPL) can be calculated in decibel.

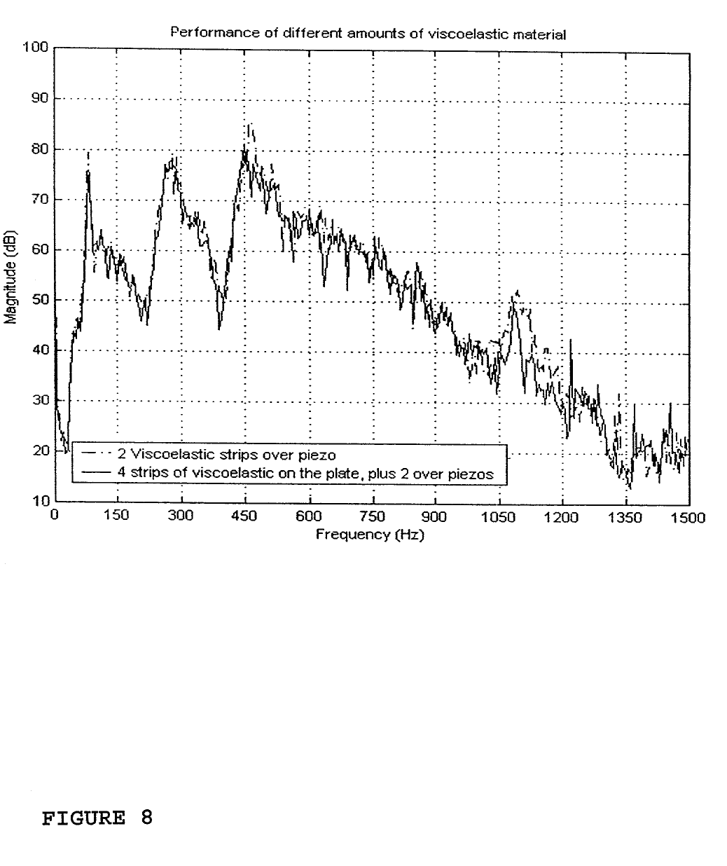

The inventors have found that additional viscoelastic material only slightly reduces the sound radiated, and therefore the performance gained by adding more viscoelastic material is not worth the additional weight. FIG. 8 illustrates the comparison the radiated sound of the bare plate (with piezoceramic actuators bonded to it, but not connected) to the sound radiated when the viscoelastic patches 1-6 as shown in FIG. 7 are applied to the plate, but no active control is used.

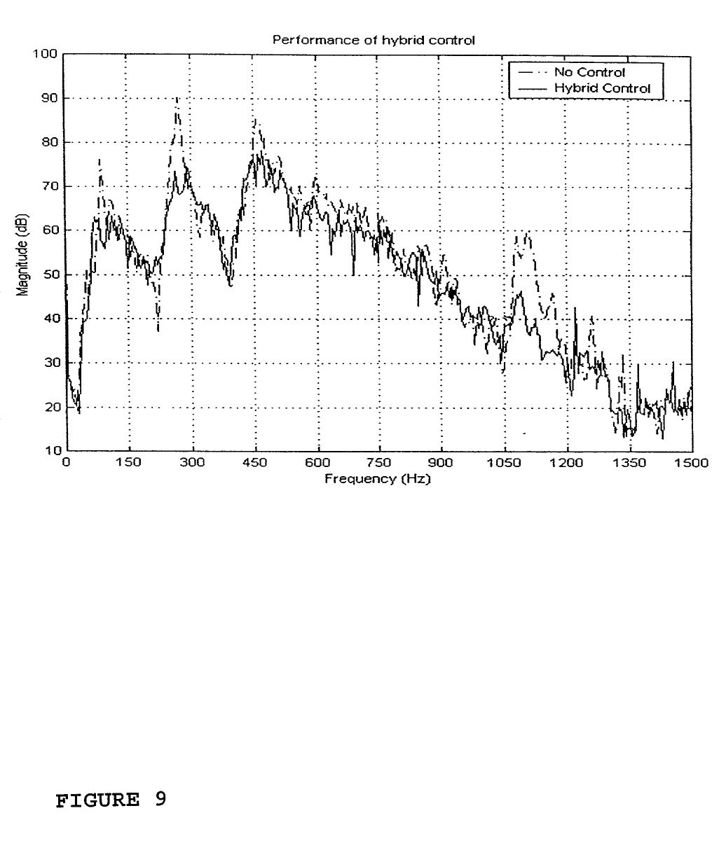

FIG. 9 illustrates the performance of the hybrid control. In this case, the active control loop is shunted and the viscoelastic patches 1-6 are applied to the plate. As discussed above, the inventors have found that the active control reduces the sound radiation for the lower modes, the passive solution reduces the sound radiation for the medium and high frequencies, while the hybrid solution reaches the full sound spectrum. It can also be noted that the active control works slightly better in the presence of viscoelastic, and that the passive control on the other hand is not disturbed by the presence of an active closed loop on the piezoceramic actuators.

### EQUIVALENTS

While the invention has been particularly shown and described with reference to specific embodiments, it should be understood by those skilled in the art that various changes in form and detail may be made therein without departing from the spirit and scope of the invention as defined by the appended claims.

What is claimed is:

1. A device for reducing vibration in a section of material, said vibration causing an acoustic disturbance in a range of frequencies detectable by a target, the device comprising:
an active damper comprising an electroactive element in electrical communication with an electrode, the active damper located a first distance from said section of material;
a passive damper comprising a sound reducing material, said passive damper
located a second distance from said section of material, wherein said second distance is greater than said first distance, and wherein at least one of the active damper and the passive damper reduces the magnitude of the acoustic disturbance reaching the target.

2. The device of claim 1, further including a constraining layer disposed in contact with said passive damper.

3. The device of claim 2, wherein the constraining layer is aluminum.

4. The device of claim 1, wherein the active damper further comprises a flexible insulator upon which said electrode is disposed.

5. The device of claim 4, wherein the electroactive element is bonded to the insulator so that in-plane strain in said electroactive element is effectively shear coupled between said electroactive element and said flexible insulator.

6. The device of claim 1, wherein said active damper damps low frequency acoustic disturbances and said passive damper damps high frequency acoustic disturbances.

7. The device of claim 1, wherein the sound reducing material comprises a viscoelastic material.

8. The device of claim 1, wherein said viscoelastic material is selected from the group of viscoelastic materials consisting of: 3M Damping Foil, Soundcoat Soundfoil, EAR Tad Pad and Sorbothane.

9. The device of claim 1, wherein said active damper is in mechanical contact with said section of material.

10. The device of claim 1, further comprising a protective, insulating encapsulation layer substantially surrounding the active damper and the passive damper.

11. The device of claim 1, wherein the active damper comprises a QuickPack® actuator.

12. The device of claim 1, wherein the active damper further comprises a compensator including at least one positive position feedback (PPF) filter implemented on a digital signal processor (DSP).

13. The device of claim 2, wherein the total mass of the device does not exceed approximately 50 grams.

14. The device of claim 2, wherein the thickness of the passive damper is about 0.005 inches, the thickness of the constraining layer is about 0.010 inches and the total thickness of the device is about 0.030 inches.

15. A device for reducing audible noise in a vehicle by reducing vibration of a vehicle section, comprising:
an actuator attached to a surface of the vehicle section, the actuator comprising at least one piezoelectric element and at least one electrode;
a viscoelastic portion which is located outside the actuator with respect to the surface of vehicle section; and
a constraining layer having a higher stiffness than said viscoelastic portion; wherein the at least one piezoelectric element and the at least one electrode are in electrical communication with each other; the constraining layer is in mechanical contact with the viscoelastic layer and wherein the device functions to reduce noise by the actuator damping specific sound modes and by the viscoelastic portion damping all of the sound modes.

16. A method of constructing the device of claim 1, comprising the steps of:
optimizing a dimension of the device by calculating an optimal dimension for said active damper and by calculating an optimal dimension for said passive damper;
modeling the behavior of the device to generate an optimal controller which governs when the active damper is energized and de-energized;
bonding an optimally dimensioned active damper to an optimally dimensioned passive damper; and
connecting the device so that the device in operation can be governed according to the optimal controller.

17. The method of claim 16, wherein the step of optimizing a dimension of the device further includes the step of optimizing an induced strain that the device is theoretically produce on the section of material.

18. A method of damping vibration in a section of material, said vibration causing noise audible to a human ear, comprising the steps of:
bonding an actuator having active damping means and passive damping means to a desired portion of the section of material;
activating the active damping means to damp low frequency vibration in the section of material;
wherein the active damping means and the passive damping means together reduce noise to a greater extent than would be possible if the active damping means or the passive damping means act alone.
